(19) United States
(12) Patent Application Publication
(10) Pub. No.: US 2013/0248875 A1
(43) Pub. Date: Sep. 26, 2013

(54) LIGHT-EMITTING DIODE COMPRISING STACKED-TYPE SCATTERING LAYER AND MANUFACTURING METHOD THEREOF

(71) Applicant: FORMOSA EPITAXY INCORPORATION, TAOYUAN (TW)

(72) Inventors: WEN-YU LIN, Taichung City (TW); LIANG-WEN WU, TAOYUAN (TW)

(73) Assignee: FORMOSA EPITAXY INCORPORATION, TAOYUAN (TW)

(21) Appl. No.: 13/847,435

(22) Filed: Mar. 19, 2013

(30) Foreign Application Priority Data
Mar. 21, 2012 (TW) 101109721

(51) Int. Cl. H01L 33/32

(52) U.S. Cl. CPC H01L 33/32
USPC 257/76; 438/29

(57) ABSTRACT

Disclosed is a light-emitting diode with a semiconductor layer including stacked-type scattering layer, and a manufacturing method thereof. The semiconductor layer includes a non-flat structure and at least two scattering layers disposed therein. The scattering layers are stacked on the non-flat structure. The top surface of each layer of the scattering layers is non-flat having an undulating fashion, and refractive indices of two adjacent layers of the scattering layers are different from each other. Photons emitted from the active layer are scattered by the scattering layers as photon scattering structure so that the probability of photons escaping from the light-emitting diode is increased, and thus total internal reflection is reduced, thereby increasing the extraction efficiency; in addition, the lateral epitaxial growth mode is enhanced, resulting in direction change of threading dislocations or formation of dislocation loops, and thus the defect density is reduced, thereby increasing the internal quantum efficiency.

### BACKGROUND OF THE INVENTION

1. Field of the Invention

The present invention generally relates to a light-emitting diode (LED) with a semiconductor layer including stacked-type scattering layer and a manufacturing method thereof, and particularly relates to a light-emitting diode capable of reducing total internal reflection, reducing defect density, and increasing the external quantum efficiency.

2. The Prior Arts

GaN-based light-emitting diodes (LEDs) can be manufactured for emitting a variety of light by controlling the composition of materials, and related technologies have therefore become the focus of active research and development in industry and academia in recent years. One research priority of academia and industry for GaN-based LEDs is to understand the luminous characteristics of GaN-based LEDs and to propose a method for increasing the external quantum efficiency and brightness of GaN-based LEDs. GaN-based LEDs with high external quantum efficiency and high brightness can be effectively used in outdoor display panel, automotive lighting, and other applications.

The external quantum efficiency of GaN-based LEDs is mainly related to the internal quantum efficiency and the extraction efficiency of GaN-based LEDs. The internal quantum efficiency is related to the probability of photon generation through recombination of electrons and holes in the active layer of a GaN-based LED. The more easily electrons and holes recombine, the more photons generated, the higher the internal quantum efficiency obtained, and also the higher the external quantum efficiency achieved. The extraction efficiency is related to the probability of photons not being absorbed by and successfully escaping from a GaN-based LED. The more photons escaping to the outside of the GaN-based LED, the higher the extraction efficiency obtained, and also the higher the external quantum efficiency achieved.

Referring to Taiwan Patent No. 1327380, a manufacturing method of a solid state light-emitting device and its application were disclosed. FIG. 1 shows a schematic view illustrating the structure cross-section of the solid state light-emitting device. As shown in FIG. 1, the solid state light-emitting device includes an epitaxial substrate 100 having a patterned mask layer 102a formed thereon. The patterned mask layer 102a is formed by depositing a dielectric material layer on the epitaxial substrate 100, performing a process such as photolithography to the dielectric material layer to define the pattern thereof, and removing by etching for example portions of the dielectric material layer to form three-dimensional patterned structure 106 having a plurality of openings 104. A portion of the surface 100a of the epitaxial substrate 100 is exposed by the openings 104. The dielectric material layer is preferably a high-reflectance stacked structure of multi-layer thin films (for example, a distributed Bragg reflector (DBR) or a one-dimensional photonic crystal reflector (PCR)) formed on the epitaxial substrate 100.

The shortcomings in the above prior art is that the reflection regions of the distributed Bragg reflector formed on the epitaxial substrate are flat interfaces which result in reduction of photon scattering. Also, the stress issue must be resolved in forming the patterned mask layer, otherwise defect density, which suppresses recombination of electrons and holes, will increase in the subsequently formed LED epitaxial films. Therefore, an LED is needed which provides a comprehensive scattering structure in order to increase the light extraction rate and effectively reduce defect density.

### SUMMARY OF THE INVENTION

An objective of the present invention is to provide a light-emitting diode with increased extraction efficiency, wherein a semiconductor layer of the light-emitting diode includes at least two scattering layers disposed therein and function as photon scattering structure in order to increase the probability of photons escaping from the light-emitting diode, and thus total internal reflection is reduced, thereby increasing the extraction efficiency.

Another objective of the present invention is to provide a light-emitting diode with reduced defect density, wherein a semiconductor layer of the light-emitting diode includes at least two scattering layers disposed therein, the top surface of each layer of the scattering layers is non-flat having an undulating fashion, thereby enhancing the lateral epitaxial growth mode, which results in direction change of threading dislocations or formation of dislocation loops, and thus the defect density is reduced, thereby increasing the internal quantum efficiency.

In order to achieve the above objectives, in one aspect, the present invention provides a light-emitting diode with a semiconductor layer including stacked-type scattering layer, which comprises: a semiconductor layer including a non-flat structure and at least two scattering layers stacked on the non-flat structure, the top surface of each layer of the scattering layers is non-flat having an undulating fashion, and refractive indices of two adjacent layers of the scattering layers are different from each other.

In another aspect, the present invention provides a method for manufacturing a light-emitting diode, comprising the following steps: forming a first portion of a semiconductor layer upon a substrate; treating the top surface of the first portion of the semiconductor layer into a non-flat structure; stacking at least two scattering layers upon the non-flat structure; and forming a second portion of the semiconductor layer upon the scattering layers, wherein refractive indices of two adjacent layers of the scattering layers are different from each other.

Accordingly, the present invention can solve the problems of the prior art. In the present invention, photons emitted from the active layer are scattered by the scattering layers as photon scattering structure so that the probability of photons escaping from the light-emitting diode is increased, and thus total internal reflection is reduced, thereby increasing the extraction efficiency; in addition, the lateral epitaxial growth mode is enhanced, resulting in direction change of threading dislocations or formation of dislocation loops, and thus the defect density is reduced, thereby increasing the internal quantum efficiency.

The foregoing and other features, aspects and advantages of the present invention will be better understood from a careful reading of a detailed description provided herein below with appropriate reference to the accompanying drawings.

### BRIEF DESCRIPTION OF THE DRAWINGS

The accompanying drawings, which are incorporated in and constitute a part of this specification, illustrate embodiments consistent with the invention and, together with the description, serve to explain the principles of the invention.

FIG. 1 shows a schematic view illustrating the structure cross-section of a solid state light-emitting device according to the prior art.

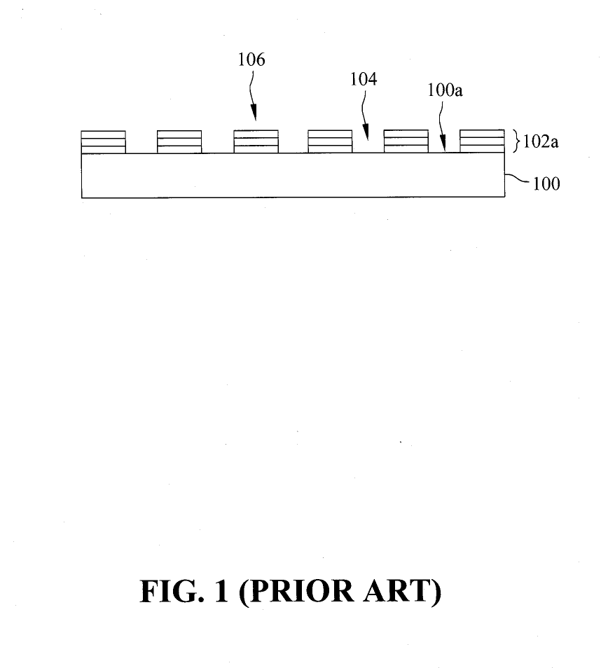

FIG. 2 shows a schematic cross-sectional view illustrating a semiconductor layer including stacked-type scattering layer for a light-emitting diode according to one embodiment of the present invention.

FIG. 3 shows a schematic view illustrating the light-emitting diode with a semiconductor layer including stacked-type scattering layer according to one embodiment of the present invention.

FIG. 4 shows a schematic cross-sectional view illustrating a method for manufacturing a semiconductor layer including stacked-type scattering layer for a light-emitting diode according to one embodiment of the present invention.

FIG. 5 shows a schematic cross-sectional view illustrating a method for manufacturing a semiconductor layer including stacked-type scattering layer for a light-emitting diode according to one embodiment of the present invention.

FIG. 6 shows a schematic cross-sectional view illustrating a method for manufacturing a semiconductor layer including stacked-type scattering layer for a light-emitting diode according to one embodiment of the present invention.

### DETAILED DESCRIPTION OF THE PREFERRED EMBODIMENT

In the following detailed description, for purposes of explanation, numerous specific details are set forth in order to provide a thorough understanding of the disclosed embodiments. It will be apparent, however, that one or more embodiments can be practiced without these specific details. In other instances, well-known structures and devices are schematically shown in order to simplify the drawing.

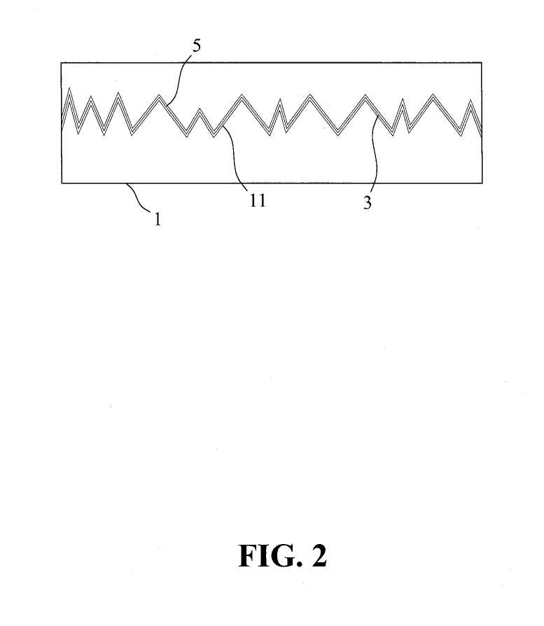

FIG. 2 shows a schematic cross-sectional view illustrating a semiconductor layer including stacked-type scattering layer for a light-emitting diode (LED) according to one embodiment of the present invention. As shown in FIG. 2, an LED according to the present invention comprises a semiconductor layer 1 including stacked-type scattering layers 3 and 5, and the semiconductor layer 1 can include at least one material selected from the group comprising an element semiconductor, a compound semiconductor, or other suitable semiconductor materials, wherein the compound semiconductor can be selected from binary, ternary or quaternary III-V compound semiconductor materials such as gallium arsenide (GaAs), gallium nitride (GaN) or other compound semiconductors.

The semiconductor layer 1 includes a first portion, wherein the top surface of the first portion is treated into a non-flat structure 11 having an undulating fashion, and at least two scattering layers 3 and 5 are stacked on the non-flat structure 11, as well as a second portion disposed on the scattering layers. The top surface of each layer of the scattering layers 3 and 5 is non-flat having an undulating fashion, thereby enhancing the lateral epitaxial growth mode, which results in direction change of threading dislocations or formation of dislocation loops, and thus the defect density is reduced, thereby increasing the internal quantum efficiency.

The at least two scattering layers 3 and 5, which are formed by stacking at least two material layers with different refractive indices, the top surface each layer being non-flat having an undulating fashion, function as photon scattering structure, and photons emitted from the active layer (not shown) will be scattered when they travel through the at least two scattering layers 3 and 5, and thus the probability of photons escaping from the light-emitting diode will be increased, thereby increasing the extraction efficiency. According to one embodiment of the present invention, the top surface of each layer of the scattering layers retains the pattern of the non-flat structure.

The two scattering layers 3 and 5 shall include at least one material having wide energy bandgap in order to prevent photon absorption and lattice constant relatively matched to nitride semiconductors in order to reduce defect density. When more than two scattering layers are used, refractive indices of two adjacent layers of the scattering layers shall be different from each other. The bigger the difference between refractive indices of two adjacent layers of the scattering layers, the better the light is scattered. According to one preferred embodiment of the present invention, the two scattering layers 3 and 5 include at least one material selected from the group comprising aluminum nitride (AlN), indium nitride (InN), gallium nitride (GaN), chromium nitride (CrN), titanium nitride (TiN), and other appropriate nitrides.

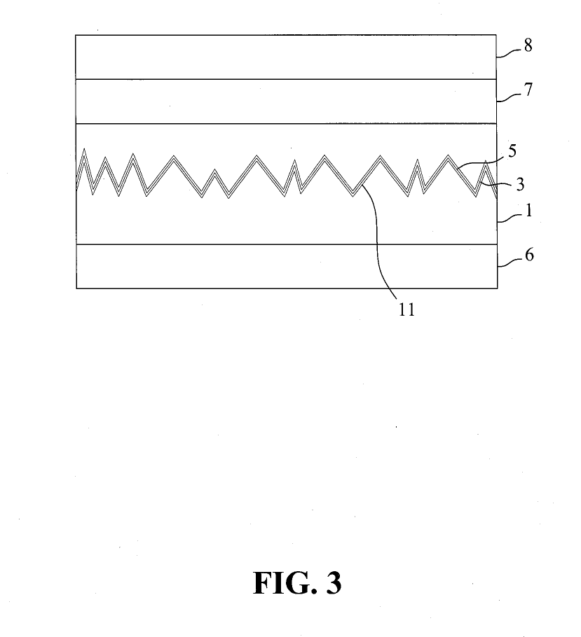

FIG. 3 shows a schematic view illustrating a light-emitting diode with a semiconductor layer including stacked-type scattering layer according to one embodiment of the present invention. As shown in FIG. 3, the semiconductor layer 1 is disposed on a substrate 6, and then an active layer 7 and a first semiconductor layer 8 are sequentially disposed on the semiconductor layer 1.

When current passes through the active layer 7, electrons and holes in the active layer 7 recombine and energy is released in the form of emitted photons. The photons in the upper half portion of the active layer 7 have the opportunity to escape swiftly from the light-emitting diode, but the photons in the lower half portion of the active layer 7 move toward the substrate 6. In the present invention, there are at least two scattering layers 3 and 5 within the semiconductor layer 1, so that the photons can be comprehensively scattered by the at least two scattering layers 3 and 5 as photon scattering structure, enabling escape from the light-emitting diode, and thus the total internal reflection effect is reduced, thereby increasing the extraction efficiency.

If the semiconductor layer 1 is an n-type GaN-based semiconductor, the first semiconductor layer 8 will be a p-type GaN-based semiconductor. If the semiconductor layer 1 is a p-type GaN-based semiconductor, the first semiconductor layer 8 will be an n-type GaN-based semiconductor. However, the various examples of the semiconductor layer 1 including at least two scattering layers 3 and 5 which are able to scatter photons out of the light-emitting diode all fall within the scope of the present invention.

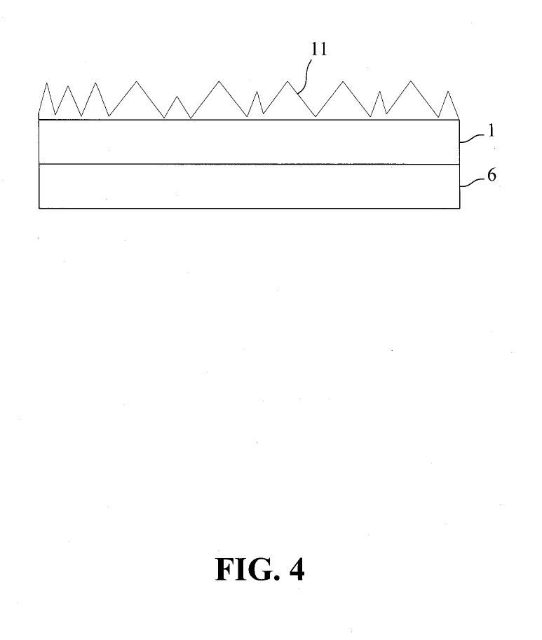

FIGS. 4-6 show the schematic cross-sectional views illustrating a method for manufacturing a semiconductor layer including stacked-type scattering layer for a light-emitting diode according to one embodiment of the present invention. As shown in FIG. 4, a first portion of a semiconductor layer 1 is formed upon a substrate 6, and the top surface part of the first portion of the semiconductor layer 1 is treated into a non-flat structure 11 having an undulating fashion. The substrate 6 can be selected from a substrate base, an epitaxial layer, a metal layer, an active layer or other suitable component. The semiconductor layer 1 can include at least one material selected from the group comprising an element semiconductor, a compound semiconductor or other suitable semiconductor materials, wherein the compound semiconductor can be selected from binary, ternary or quaternary III-V compound semiconductor material, such as gallium arsenide (GaAs), gallium nitride (GaN) or other compound semiconductors.

The non-flat structure 11 is formed by performing a surface treatment on the first portion of the semiconductor layer 1. For example, the first portion of the semiconductor layer 1 is grinded to form an irregular non-flat structure thereon, or the first portion of the semiconductor layer 1 is reactive-ion etched (RIE) to form a regular or periodic non-flat structure thereon.

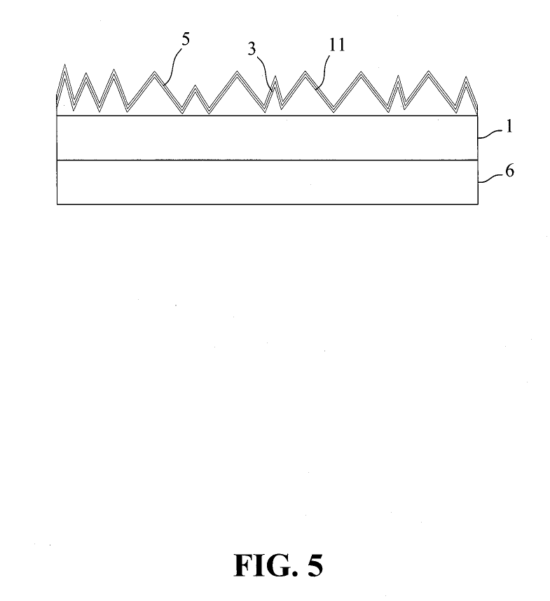

Then, as shown in FIG. 5, at least two scattering layers 3 and 5 are stacked upon the non-flat structure 11, the refractive indices of the scattering layers 3 and 5 being different from each other. The two scattering layers 3 and 5 shall include at least one material having wide energy bandgap in order to prevent photon absorption and lattice constant relatively matched to nitride semiconductors in order to reduce defect density. When more than two scattering layers are stacked, refractive indices of two adjacent layers of the scattering layers shall be different from each other. The bigger the difference between refractive indices of two adjacent layers of the scattering layers, the better the photons are scattered. According to one preferred embodiment of the present invention, the two scattering layers 3 and 5 include at least one material selected from the group comprising aluminum nitride (AlN), indium nitride (InN), gallium nitride (GaN), chromium nitride (CrN), titanium nitride (TiN), and other appropriate nitrides.

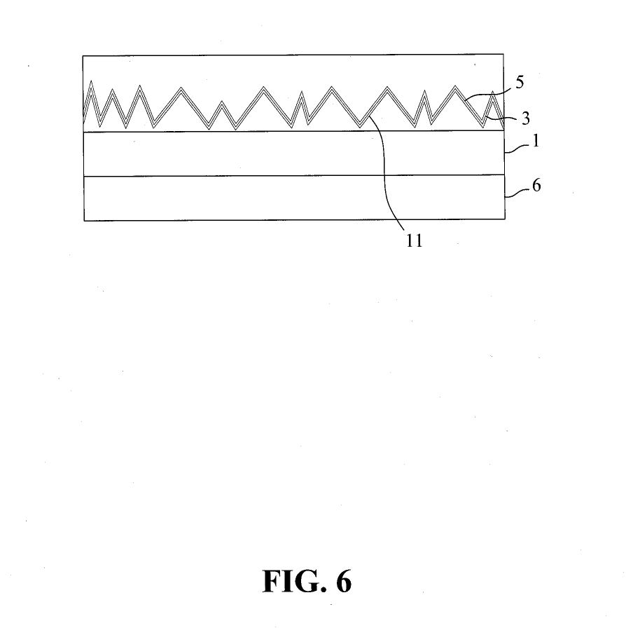

Finally, as shown in FIG. 6, the second portion of the semiconductor layer 1 is formed upon the two scattering layers 3 and 5. The manufacturing process of the present invention can be integrated with the manufacturing process of light-emitting diodes to increase the external quantum efficiency of light-emitting diodes.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A light-emitting diode comprising:
a semiconductor layer comprising:
a first portion, wherein the top surface of said first portion is treated into a non-flat structure;
at least two nitride-based scattering layers stacked on said non-flat structure; and
a second portion disposed on said nitride-based scattering layers,
wherein the top surface of each layer of said nitride-based scattering layers is non-flat, and refractive indices of two adjacent layers of said nitride-based scattering layers are different from each other.

2. The light-emitting diode of claim 1, wherein said semiconductor layer is disposed on a substrate.

3. The light-emitting diode of claim 2, wherein said substrate is selected from a substrate base, an epitaxial layer, a metal layer, or an active layer.

4. The light-emitting diode of claim 2, wherein said semiconductor layer is interposed between said substrate and an active layer.

5. The light-emitting diode of claim 1, wherein said semiconductor layer includes at least one material selected from the group comprising an element semiconductor and a compound semiconductor.

6. The light-emitting diode of claim 1, wherein said non-flat structure is irregular.

7. The light-emitting diode of claim 1, wherein said non-flat structure is regular or periodic.

8. The light-emitting diode of claim 1, wherein said nitride-based scattering layer includes at least one material with wide energy bandgap.

9. The light-emitting diode of claim 1, wherein said nitride-based scattering layer includes at least one material with lattice constant relatively matched to nitride semiconductors.

10. The light-emitting diode of claim 1, wherein said nitride-based scattering layer includes at least one material selected from the group comprising aluminum nitride, indium nitride, gallium nitride, chromium nitride, and titanium nitride.

11. The light-emitting diode of claim 1, wherein the top surface of each layer of said nitride-based scattering layers has an undulating fashion.

12. The light-emitting diode of claim 1, wherein the top surface of each layer of said nitride-based scattering layers retains the pattern of said non-flat structure.

13. A method for manufacturing a light-emitting diode, comprising:
forming a first portion of a semiconductor layer upon a substrate;
treating the top surface of said first portion of said semiconductor layer into a non-flat structure;
stacking at least two nitride-based scattering layers upon said non-flat structure; and
forming a second portion of said semiconductor layer upon said nitride-based scattering layers,
wherein refractive indices of two adjacent layers of said nitride-based scattering layers are different from each other.

14. The method of claim 13, further comprising:
forming an active layer upon said semiconductor layer.

15. The method of claim 13, wherein said substrate is selected from a substrate base, an epitaxial layer, a metal layer, or an active layer.

16. The method of claim 13, wherein said semiconductor layer includes at least one material selected from the group comprising an element semiconductor and a compound semiconductor.

17. The method of claim 13, wherein said non-flat structure is irregular.

18. The method of claim 13, wherein said non-flat structure is regular or periodic.

19. The method of claim 13, wherein said nitride-based scattering layer includes at least one material with wide energy bandgap.

20. The method of claim 13, wherein said nitride-based scattering layer includes at least one material with lattice constant relatively matched to nitride semiconductors.

21. The method of claim 13, wherein said nitride-based scattering layer includes at least one material selected from the group comprising aluminum nitride, indium nitride, gallium nitride, chromium nitride, and titanium nitride.

22. The method of claim 13, wherein the top surface of each layer of said nitride-based scattering layers is non-flat.

23. The method of claim 13, wherein the top surface of each layer of said nitride-based scattering layers has an undulating fashion.

24. The method of claim 13, wherein the top surface of each layer of said nitride-based scattering layers retains the pattern of said non-flat structure.
